(19) United States
(12) Patent Application Publication
(10) Pub. No.: US 2023/0186822 A1
(43) Pub. Date: Jun. 15, 2023

(54) CHIP ON FILM AND DISPLAY PANEL

(71) Applicant: Shenzhen China Star Optoelectronics Semiconductor Display Technology Co., Ltd., Shenzhen (CN)

(72) Inventor: Yingchun ZHAO, Shenzhen (CN)

(21) Appl. No.: 16/972,594

(22) PCT Filed: Nov. 25, 2020
(86) PCT No.: PCT/CN2020/131503

§ 371 Date: Dec. 6, 2020

(30) Foreign Application Priority Data
Sep. 3, 2020 (CN) 202010914597.6

(51) Int. Cl. G09G 3/20

(52) U.S. Cl. CPC G09G 3/2092; G09G 2310/0267; G09G 2310/0275

(57) ABSTRACT

The present disclosure provides a chip on film and a display panel. The chip on film includes a film body, gate driving chips and source driving chips integrated and arranged on the film body and bonding wires. The display panel includes a plurality of chip on films. A gate chip on film disposed on a left side and a right side of a display area of the display panel and at least part of the source chip on film disposed on an upper side and a lower side of the display area are combined into one chip on film, so that a double-row bonding wires design may be avoided, thereby being beneficial to realize an extremely narrow border.

### FIELD OF INVENTION

The present disclosure relates to the field of display technologies, and particularly relates to a chip on film and a display panel.

### BACKGROUND OF INVENTION

While an overall design of televisions (TVs) becomes more and more aesthetically pleasing, a design of reducing borders of display panels has become an important direction. Gate driving units and source driving units are generally designed with gate chip on films (COF) and source chip on films respectively. A structure of a conventional display panel is that the source chip on films are arranged on one of an upper end and a lower end of the display panel, and the gate chip on films are arranged on one of a left end and a right end of the display panel. However, because the source driving units and the gate driving units respectively occupy peripheral areas of the display panel, the peripheral areas of the display panel are made wider, so border areas of the display panels occupy a larger space, which affects visual effect of images displayed.

In a narrow border design, there is a design scheme that places the gate driving units on a side of the source driving units, that is, the gate chip on films are placed on a side of the source chip on films. In this way, a “three narrow and one wide” border design can be realized. However, because the gate chip on films and the source chip on films are independently bound. In one case, as shown in FIG. 1, the gate chip on films 21 and the source chip on films 22 are disposed on the gate driving chips 211 and the source driving chips 221 respectively, and a first row of bonding wires 212 and a second row of the bonding wires 222 are used respectively, which may cause a width of the bonding wires to be doubled and could hamper a narrow border design. In another case, as shown in FIG. 2, the gate chip on films 21 and the source chip on films 22 share the same first row of the bonding wires 212, so it is difficult to realize bonding due to an excessive number of chip on films and limited design space of the display panel.

In summary, a new chip on film and a new display panel need to be provided to solve the above-mentioned technical problems.

### Technical Problems

A chip on film and a display panel provided in the present disclosure solve technical problems that gate chip on films are placed on a side of source chip on films in display panels of prior art, when the gate chip on films and the source chip on films are independently bound, it is not unbeneficial to realize a narrow border.

### Technical Solutions

In order to solve the above problems, the present disclosure provides technical solutions as followings:

An embodiment of the present disclosure provides a display panel, including a display area and a non-display area surrounding the display area, the display area including a first side and a second side opposite to the first side, a plurality of scanning lines and a plurality of data lines crossed with the scanning lines;

the display panel including a plurality of chip on films, the chip on films are disposed in the non-display area on one of the first side and the second side of the display area, and each of the chip on films including:

a film body, wherein a shape of the film body is any one of a trapezoid, a rectangle, and a regular hexagon;

gate driving chips and source driving chips integrated and arranged on the film body and configured to provide gate driving signals and source driving signals; and

bonding wires arranged on a side of the film body, configured to bond and connect grid wires of the gate driving chips to the scanning lines, and bond and connect source wires of the source driving chips to the data lines.

According to the display panel provided in an embodiment of the present disclosure, the display panel at least includes a first metal layer and a second metal layer, the scanning lines are arranged in the first metal layer, and the data lines are arranged in the second metal layer.

According to the display panel provided in an embodiment of the present disclosure, the grid wires and the source wires are arranged in a same layer, the grid wires and the source wires are arranged in the first metal layer, or the grid wires and the source wires are arranged in the second metal layer.

According to the display panel provided in an embodiment of the present disclosure, the grid wires and the source wires are arranged in different layers, the grid wires are arranged in one of the first metal layer and the second metal layer, and the source wires are arranged in another one of the first metal layer and the second metal layer.

According to the display panel provided in an embodiment of the present disclosure, an insulating layer is disposed between the grid wires and the source wires.

According to the display panel provided in an embodiment of the present disclosure, the grid wires and the source wires are respectively arranged on a side of the gate driving chips and a side of the source driving chips close to the display area.

According to the display panel provided in an embodiment of the present disclosure, part of the grid wires and/or the source wires spans to sides of the gate driving chips and the source driving chips away from the display area.

According to the display panel provided in an embodiment of the present disclosure, the display panel includes a plurality of first fan-out lines and a plurality of second fan-out lines disposed at a side of the chip on films close to the display area, the first fan-out lines electrically connect the grid wires to the scanning lines through the bonding wires, and the second fan-out lines electrically connect the source wires to the data lines through the bonding wires.

According to the display panel provided in an embodiment of the present disclosure, a total number of the gate driving chips on the display panel is equal to a total number of the source driving chips.

According to the display panel provided in an embodiment of the present disclosure, the grid wires and the source wires adopt a design of three-layer wirings.

An embodiment of the present disclosure provides a chip on film, including:

a film body;

gate driving chips and source driving chips integrated and arranged on the film body and configured to provide gate driving signals and source driving signals; and

bonding wires arranged on a side of the film body, configured to bond and connect grid wires of the gate driving chips to the scanning lines, and configured to bond and connect source wires of the source driving chips to the data lines.

According to the chip on film provided in an embodiment of the present disclosure, the grid wires and the source wires are arranged in a same layer.

According to the chip on film provided in an embodiment of the present disclosure, the grid wires and the source wires are arranged in different layers.

According to the chip on film provided in an embodiment of the present disclosure, an orthographic projection of ends of the grid wires and the bonding wires bonded and connected, and an orthographic projection ends of the source wires and the bonding wires bonded and connected are arranged at intervals on the film body.

An embodiment of the present disclosure provides a display panel, including a display area and a non-display area surrounding the display area, the display area including a first side and a second side opposite to the first side, and a plurality of scanning lines and a plurality of data lines crossed with the scanning lines;

the display panel including a plurality of chip on films;

the chip on films are disposed in the non-display area on one of the first side and the second side of the display area, each of the chip on films including:

a film body;

gate driving chips and source driving chips, integrated and arranged on the film body, for providing gate driving signals and source driving signals; and

bonding wires, arranged on a side of the film body, for bonding and connecting grid wires of the gate driving chips to the scanning lines and for bonding and connecting source wires of the source driving chips to the data lines.

According to the display panel provided in an embodiment of the present disclosure, the display panel at least includes a first metal layer and a second metal layer, the scanning lines are arranged in the first metal layer, and the data lines are arranged in the second metal layer.

According to the display panel provided in an embodiment of the present disclosure, the grid wires and the source wires are arranged in a same layer, the grid wires and the source wires are arranged in the first metal layer, or the grid wires and the source wires are arranged in the second metal layer.

According to the display panel provided in an embodiment of the present disclosure, the grid wires and the source wires are arranged in different layers, the grid wires are arranged in one of the first metal layer and the second metal layer, and the source wires are arranged in another one of the first metal layer and the second metal layer.

According to the display panel provided in an embodiment of the present disclosure, an insulating layer is disposed between the grid wires and the source wires.

According to the display panel provided in an embodiment of the present disclosure, the display panel includes a plurality of first fan-out lines and a plurality of second fan-out lines disposed at a side of the chip on films close to the display area, the first fan-out lines electrically connect the grid wires to the scanning lines through the bonding wires, and the second fan-out lines electrically connect the source wires to the data lines through the bonding wires.

### Beneficial Effects

Beneficial effects of the present disclosure are: in a chip on film and a display panel provided in the present disclosure, a gate chip on film disposed on a left side and a right side of a display area of the display panel and at least part of the source chip on film disposed on an upper side and a lower side of the display area are combined into one chip on film, the chip on film includes integrated gate driving chips and integrated source driving chips, a row of bonding wires are arranged on a side of the chip on film adjacent to the display area. The bonding wires are configured to bond and connect the grid wires of the gate driving chips to scanning lines, and are configured to bond and connect the source wires of the source driving chips to data lines, so a double-row bonding wires design may be avoided, meanwhile, it is beneficial to further compress space of the display panel at a side of the source chip on films, thereby realizing an extremely narrow border design.

### DESCRIPTION OF DRAWINGS

The accompanying drawings to be used in the description of embodiments of the present disclosure or prior art will be described in brief to more clearly illustrate the technical solutions of the embodiments or the prior art. The accompanying drawings described below are only part of the embodiments of the present disclosure. For those of ordinary skill in the art, other drawings can be obtained from these drawings without creative work.

FIG. 1 is a bonding schematic diagram of a chip on film in the prior art.

FIG. 2 is another bonding schematic diagram of a chip on film in the prior art.

FIG. 3 is a schematic structural diagram of a chip on film provided by an embodiment of the present disclosure.

FIG. 4 is a schematic plan diagram of a display panel provided by the embodiment of the present disclosure.

FIG. 5 is a sectional structural schematic diagram of the display panel provided by the embodiment of the present disclosure.

FIG. 5A is a schematic diagram of a wiring arrangement of the chip on film of the display panel in FIG. 5.

FIG. 6 is another sectional structural schematic diagram of a display panel provided in an embodiment of the present disclosure.

FIG. 6A is a schematic diagram of a wiring arrangement of the chip on film of the display panel in FIG. 6.

FIG. 6B is another schematic diagram of a wiring arrangement of the chip on film of the display panel in FIG. 6.

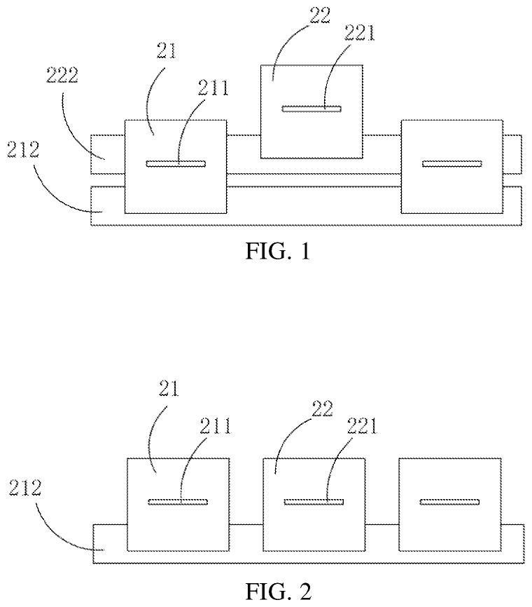

### DETAILED DESCRIPTION OF EMBODIMENTS

The following description of the various embodiments is provided to illustrate the specific embodiments. Directional terms described by the present disclosure, such as “top”, “bottom”, “front”, “back”, “left”, “right”, “inner”, “outer”, “side”, etc., are only directions by referring to the accompanying drawings, and thus the used terms are used only for the purpose of describing embodiments of the present disclosure and are not intended to be limiting of the present disclosure. In the drawings, units with similar structures are labeled with the same reference number.

In the description of the present disclosure, it should be understood that terms such as “center,” “longitudinal,” “lateral,” “length,” “width,” “thickness,” “upper,” “lower,” “front,” “rear,” “left,” “right,” “vertical,” “horizontal,” “top,” “bottom,” “inside,” “outside,” “clockwise,” “counter-clockwise” as well as derivative thereof should be construed to refer to the orientation as then described or as shown in the drawings under discussion. These relative terms are for convenience of description, do not require that the present disclosure be constructed or operated in a particular orientation, and shall not be construed as causing limitations to the present disclosure. In addition, terms such as “first” and “second” are used herein for purposes of description and are not intended to indicate or imply relative importance or significance. Thus, features limited by “first” and “second” are intended to indicate or imply including one or more than one these features. In the description of the present disclosure, “a plurality of” relates to two or more than two, unless otherwise specified.

In the description of the present disclosure, it should be noted that unless there are express rules and limitations, the terms such as “mount,” “connect,” and “bond” should be comprehended in broad sense. For example, it can mean a permanent connection, a detachable connection, or an integrated connection. It can mean a mechanical connection, an electrical connection, or can communicate with each other. It can mean a direct connection, an indirect connection by an intermediate, or an inner communication or an interaction between two elements. Those skilled in the art should understand the specific meanings in the present disclosure according to specific situations.

In the description of the present disclosure, unless specified or limited otherwise, it should be noted that, a structure in which a first feature is “on” or “beneath” a second feature may include an embodiment in which the first feature directly contacts the second feature and may also include an embodiment in which an additional feature is formed between the first feature and the second feature so that the first feature does not directly contact the second feature. Furthermore, a first feature “on,” “above,” or “on top of” a second feature may include an embodiment in which the first feature is right “on,” “above,” or “on top of” the second feature and may also include an embodiment in which the first feature is not right “on,” “above,” or “on top of” the second feature, or just means that the first feature has a sea level elevation greater than the sea level elevation of the second feature. While first feature “beneath,” “below,” or “on bottom of” a second feature may include an embodiment in which the first feature is right “beneath,” “below,” or “on bottom of” the second feature and may also include an embodiment in which the first feature is not right “beneath,” “below,” or “on bottom of” the second feature, or just means that the first feature has a sea level elevation less than the sea level elevation of the second feature.

The present disclosure herein provides many different embodiments or examples for realizing different structures of the present disclosure. In order to simplify the disclosure of the present disclosure, components and settings of specific examples are described below. Of course, they are only examples and are not intended to limit the present disclosure. Furthermore, reference numbers and/or letters may be repeated in different examples of the present disclosure. Such repetitions are for simplification and clearness, which per se do not indicate the relations of the discussed embodiments and/or settings. Moreover, the present disclosure provides examples of various specific processes and materials, but the applicability of other processes and/or application of other materials may be appreciated by a person skilled in the art.

The present disclosure targets chip on films and display panels in the prior art, in which gate chip on films are placed on a side of source chip on films, and the gate chip on films and the source chip on films are independently bound, which is unconducive to realizing a narrow border. This embodiment can correct these defects.

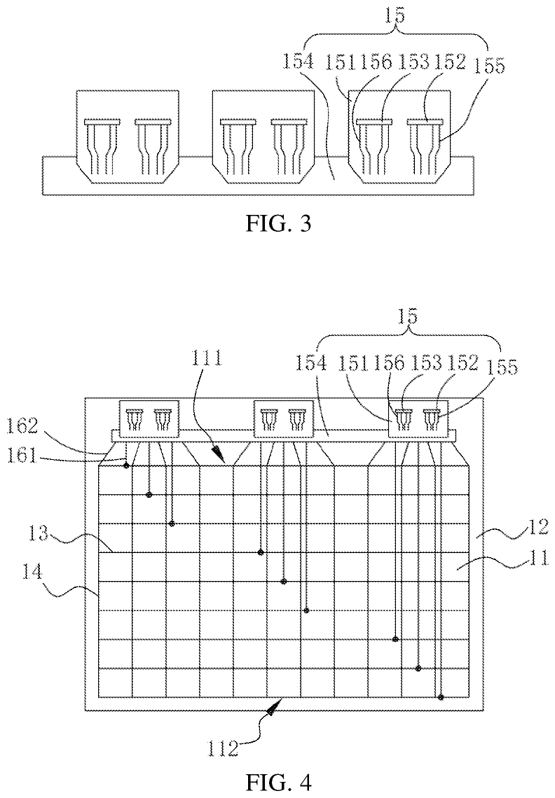

Referring to FIG. 3, a chip on film 15 provided by an embodiment of the present disclosure includes a film body 151, gate driving chips 152, source driving chips 153, and bonding wires 154. The gate driving chips 152 and the source driving chips 153 are integrated and arranged on the film body 151, the gate driving chips 152 are configured to provide gate driving signals, and the source driving chips 153 are configured to provide source driving signals. The bonding wires 154 are arranged on a side of the film body 151, the bonding wires 154 are used to bond and connect grid wires 155 of the gate driving chips 152 and source wires 156 of the source driving chips 153 to signal wires (not shown in the figure) arranged outside the chip on film 15. Wherein, the signal wires may be scanning lines and data lines. In the embodiments of the present disclosure, the bonding wires 154 are arranged on a lower side of the film body 151, the bonding wires 154 are configured to connect the gate driving chips 152 and the source driving chips 153, thereby providing signals to the signal wires.

The grid wires 155 and the source wires 156 may be arranged in a same layer, that is, the grid wires 155 and the source wires 156 are arranged in a same metal layer. Preferably, the grid wires 155 and the source wires 156 may be arranged in different layers in order to maximize integration of the chip on film 15, that is, the grid wires 155 and the source wires 156 can be arranged in different metal layers, which can further miniaturize the chip on film 15 to achieve a higher level of integration.

It should be noted that, because the gate driving chips 152 and the source driving chips 153 are integrated on the same film body 151 to form one chip on film 15 in the present disclosure, the bonding wires 154 may be arranged in only one row. That is, the gate driving chips 152 and the source driving chips 153 share a same row of the bonding wires 154. Compared with a manner in which the gate chip on films are arranged on the side of the source chip on films in the prior art, and the gate chip on films and the source chip on films are independently bound to the bonding wires arranged in different rows, the manner in the present disclosure can omit manufacturing processes and save costs.

The present invention does not make any limitation on an arrangement of the gate driving chips 152 and the source driving chips 153 on the film body 151, for example, as shown in FIG. 3, the gate driving chips 152 and the source driving chips 153 may be arranged in a horizontal direction. For another example, as shown in FIG. 4, the gate driving chips 152 and the source driving chips 153 may be arranged side by side in a vertical direction.

Similarly, the present invention does not make any limitation on a shape of the film body 151. The shape of the film body 151 may be a polygon, such as any one of a trapezoid, a rectangle, and a regular hexagon. The arrangement of the gate driving chips 152 and the source driving chips 153 on the film body 151 may be adaptively designed according to specific shapes of the film body 151 to effectively utilize space.

Referring to FIG. 4, a display panel provided by this embodiment of the present disclosure provides includes a display area 11 and a non-display area 12 surrounding the display area 11, and the display area 11 includes a first side 111 and a second side 112 opposite to the first side 111. In the embodiment of the present disclosure, the first side 111 is an upper side of the display area 11, and the second side 112 is a lower side of the display area 11. The display area 11 includes a plurality of the scanning lines 13 and a plurality of the data lines 14 crossed with the scanning lines 13. The display panel includes a plurality of the chip on films 15. The chip on films 15 are arranged in the non-display area 12 which is positioned at one of the first side 111 and the second side 112 of the display area 11. That is, the chip on films 15 are arranged on the upper side or the lower side of the display area 11. The embodiment of the present disclosure is illustrated by taking the chip on films 15 arranged on the upper side of the display area 11 as an example.

For convenience of description, the present disclosure is illustrated by taking the display panel including three chip on films 15 as an example.

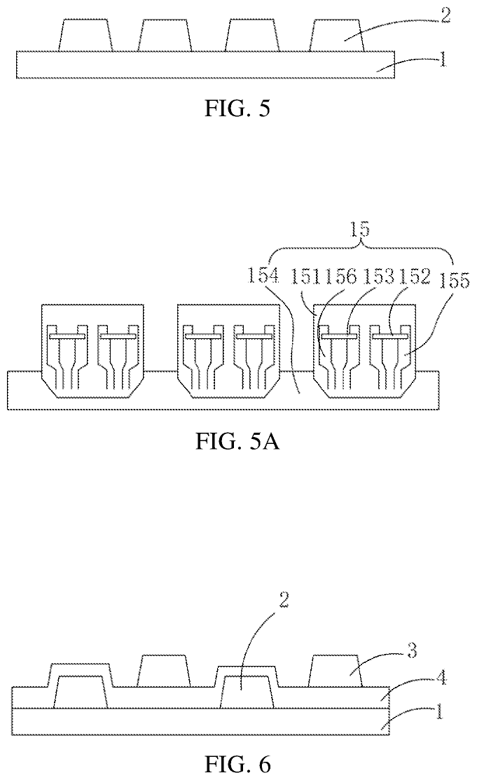

Specifically, as shown in FIG. 5, each of the chip on films 15 includes the film body 151, the gate driving chips 152, the source driving chips 153, and the bonding wires 154. The gate driving chips 152 and the source driving chips 153 are integrated and arranged on the film body 151, the gate driving chips 152 are configured to provide the gate driving signals, and the source driving chips 153 are configured to provide the source driving signals. The bonding wires 154 are arranged on the side of the film body 151 to bond and connect the grid wires 155 of the gate driving chips 152 with the scanning lines 13 and bond and connect the source wires 156 of the source driving chips 153 with the data lines 14.

In the embodiments of the present disclosure, the gate driving chips 152 and the source driving chips 153 share the same row of the bonding wires 154. Compared with the manner in which the gate chip on films are arranged on the side of the source chip on films in the prior art, and the gate chip on films and the source chip on films are independently bound to the bonding wires arranged in different rows, the manner in the present disclosure is beneficial to further compress the space of the display panel on the side of the source chip on films, thereby realizing an extremely narrow border design.

The gate driving chips 152 and the source driving chips 153 are integrated and arranged on the same film body 151 in this embodiment of the present disclosure. In comparison, in conventional chip on films, the gate driving chips 152 and the source driving chips 153 are respectively arranged on different film bodies 151 to form a gate driving unit and a source driving unit, and the gate driving unit and the source driving unit are respectively arranged on two adjacent sides of a border of the display panel. On the one hand, the gate driving unit and the source driving unit composed of the chip on films 15 provided by the embodiment of the present disclosure are integrated into a driving unit, and the driving unit is only set at one side of the border of the display panel, thereby further reducing the border of the display panel, increasing a screen-to-body ratio and achieving the extremely narrow border design; on the other hand, under conditions of setting a same area or length, the display panel provided by this embodiment of the present disclosure may be provided with a larger number of the chip on films 15. In addition, a distance between two adjacent chip on films 15 is decreased, which is beneficial to improve resolution of the display panel and meet requirements of the display panel for high resolution.

The display panel includes a substrate 1, the substrate 1 is at least provided with a first metal layer 2 and a second metal layer 3 thereon, the scanning lines 13 are arranged in the first metal layer 2, and the data lines 14 are arranged in the second metal layer 3.

A total number of the gate driving chips 152 on the display panel is equal to a total number of the source driving chips 153 on the display panel to ensure a display uniformity of the display panel. An orthographic projection of the gate driving chips 152 on the substrate 1 and an orthographic projection of the source driving chips 153 on the substrate 1 are arranged at even intervals. Taking the display panel as a conventional 8K display panel as an example, a number of the source chip on films is 24, and a number of the gate chip on films is 3-5, therefore, the 3-5 gate chip on films can be re-divided into 24 pieces, and then a single gate driving chip 152 and a single source driving chip 153 are integrated into the chip on film 15 provided by the embodiment of the present disclosure. Referring to FIG. 5, in an embodiment, the grid wires 155 and the source wires 156 are arranged in the same layer, the grid wires 155 and the source wires 156 are arranged in the first metal layer 2. Alternatively the grid wires 155 and the source wires 156 are arranged in the second metal layer 3.

The embodiments of the present disclosure do not make any limitation on an arrangement of a single wire of the grid wires 155 and the source wires 156. For example, as shown in FIG. 3, the grid wires 155 and the source wires 156 are respectively arranged on sides of the gate driving chips 152 and the source driving chips 153 close to the display area 11. For another example, as shown in FIG. 5A, part of the grid wires 155 and/or the source wires 156 may spans to sides of the gate driving chips 152 and the source driving chips 153 away from the display area 11 to effectively utilize the space for wiring.

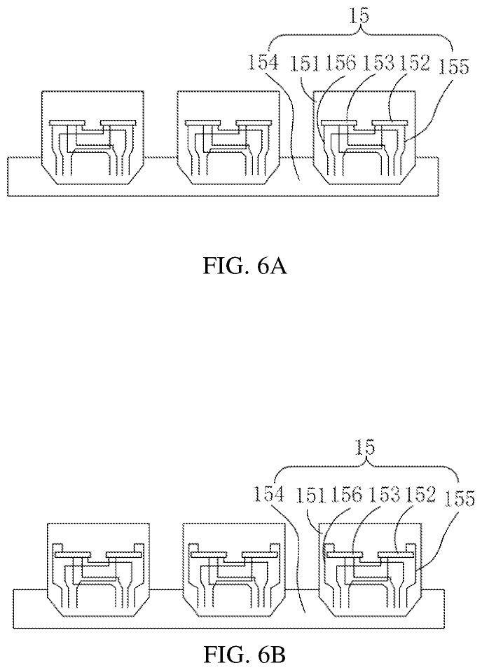

Preferably, referring to FIG. 6, in another embodiment, the grid wires 155 and the source wires 156 are arranged in different layers to further improve the integration of the chip on film 15, the grid wires 155 may be arranged in one of the first metal layer 2 and the second metal layer 3, and the source wires 156 are arranged in the other one of the first metal layer 2 and the second metal layer 3.

An insulating layer 4 is arranged between the grid wires 155 and the source wires 156 to prevent a short circuit between the grid wires 155 and the source wires 156 arranged in different layers. That is, the insulating layer 4 is arranged between the first metal layer 2 and the second metal layer 3. Wherein, the insulating layer 4 can be manufactured through a same process as manufacturing a gate insulating layer disposed in the display area 11.

Similarly, in this embodiment, there is not any limitation on the arrangement of the single wire of the grid wires 155 and the source wires 156. For example, as shown in FIG. 6A, the grid wires 155 and the source wires 156 are respectively arranged on the sides of the gate driving chips 152 and the source driving chips 153 close to the display area 11. For another example, as shown in FIG. 6B, the part of the grid wires 155 and/or the source wires 156 spans to the sides of the gate driving chips 152 and the source driving chips 153 away from the display area 11 to effectively utilize the space for wiring.

It should be noted that, the grid wires 155 and the source wires 156 adopt a double-layered metal wiring design in the embodiment of the present disclosure. However, embodiments of the present disclosure should not be limited to this. The grid wires 155 and the source wires 156 may further adopt three-layered, four-layered, or more layered metal wiring design. For example, the grid wires 155 and the source wires 156 adopt the three-layered metal wiring design. Among them, two of the layers are the source wires 156, and the other layer is the grid wires 155.

Please continue to refer to FIG. 5. The display panel includes a plurality of first fan-out lines 161 and a plurality of second fan-out lines 162 disposed at a side of the chip on films 15 close to the display area 11. The first fan-out lines 161 electrically connect the grid wires 155 to the scanning lines 13 through the bonding wires 154, and the second fan-out lines 162 electrically connect the source wires 156 to the data lines through the bonding wires 154.

It should be noted that, only one gate driving chip 152 and one source driving chip 153 are arranged on one chip on film 15 in this embodiment of the present disclosure. In other embodiments, according to actual situations, multi-gate driving chips 151 and multi-source driving chips 152 may be arranged on one chip on film 15, and the arrangement and the wiring of the gate driving chips 151 and the source driving chips 152 may refer to above-mentioned embodiments and will not be described herein.

The beneficial effects of the present disclosure are: in the chip on film and the display panel provided in the embodiments of the present disclosure, the gate chip on film disposed on the left side and the right side of the display area of the display panel and at least the part of the source chip on film disposed on the upper side and the lower side of the display area are combined into one chip on film. The chip on film includes integrated gate driving chips and integrated source driving chips. The row of bonding wires are arranged on the side of the chip on film adjacent to the display area. The bonding wires are configured to bond and connect the grid wires of the gate driving chips to the scanning lines and bond and connect the source wires of the source driving chips to data lines, hence, a double-row bonding wires design may be avoided and a total number of the chip on films was decreased, which is beneficial to further compress the space of the display panel on the side of the source chip on films and achieve the extremely narrow border design.

In summary, although the present disclosure has been disclosed as above with preferred embodiments, the above preferred embodiments are not intended to limit the present invention. Those of ordinary skill in the art can make various changes and retouching without departing from the spirit and scope of the present disclosure. Therefore, a protection scope of the present disclosure is subject to a scope defined by the claims.

What is claimed is:

1. A display panel, comprising a display area and a non-display area surrounding the display area, the display area comprising a first side and a second side opposite to the first side, a plurality of scanning lines, and a plurality of data lines crossed with the scanning lines;
the display panel comprising a plurality of chip on films, the chip on films are disposed in the non-display area on one of the first side and the second side of the display area, and each of the chip on films comprising:
a film body, wherein a shape of the film body is any one of a trapezoid, a rectangle, and a regular hexagon;
gate driving chips and source driving chips integrated and arranged on the film body and configured to provide gate driving signals and source driving signals; and
bonding wires arranged on a side of the film body, configured to bond and connect grid wires of the gate driving chips to the scanning lines, and bond and connect source wires of the source driving chips to the data lines.

2. The display panel in claim 1, wherein the display panel at least comprises a first metal layer and a second metal layer, the scanning lines are arranged in the first metal layer, and the data lines are arranged in the second metal layer.

3. The display panel in claim 2, wherein the grid wires and the source wires are arranged in a same layer, the grid wires and the source wires are arranged in the first metal layer, or the grid wires and the source wires are arranged in the second metal layer.

4. The display panel in claim 2, wherein the grid wires and the source wires are arranged in different layers, the grid wires are arranged in one of the first metal layer and the second metal layer, and the source wires are arranged in the other one of the first metal layer and the second metal layer.

5. The display panel in claim 4, wherein an insulating layer is disposed between the grid wires and the source wires.

6. The display panel in claim 5, wherein the grid wires and the source wires are respectively arranged on a side of the gate driving chips and a side of the source driving chips close to the display area.

7. The display panel in claim 5, wherein part of the grid wires and/or the source wires spans to sides of the gate driving chips and the source driving chips away from the display area.

8. The display panel in claim 1, wherein the display panel comprises a plurality of first fan-out lines and a plurality of second fan-out lines disposed at a side of the chip on films close to the display area, the first fan-out lines electrically connect the grid wires to the scanning lines through the bonding wires, and the second fan-out lines electrically connect the source wires to the data lines through the bonding wires.

9. The display panel in claim 1, wherein a total number of the gate driving chips on the display panel is equal to a total number of the source driving chips.

10. The display panel in claim 1, wherein the grid wires and the source wires adopt a design of three-layer wirings.

11. A chip on film, comprising:
a film body;
gate driving chips and source driving chips integrated and arranged on the film body and configured to provide gate driving signals and source driving signals; and
bonding wires arranged on a side of the film body, configured to bond and connect grid wires of the gate driving chips to the scanning lines, and configured to bond and connect source wires of the source driving chips to the data lines.

12. The chip on film in claim 11, wherein the grid wires and the source wires are arranged in a same layer.

13. The chip on film in claim 11, wherein the grid wires and the source wires are arranged in different layers.

14. The chip on film in claim 11, wherein an orthographic projection of ends of the grid wires and the bonding wires bonded and connected and an orthographic projection ends of the source wires and the bonding wires bonded and connected are arranged at intervals on the film body.

15. A display panel, comprising a display area and a non-display area surrounding the display area, the display area comprising a first side and a second side opposite to the first side, and a plurality of scanning lines and a plurality of data lines crossed with the scanning lines;
the display panel comprising a plurality of chip on films;
the chip on films are disposed in the non-display area on one of the first side and the second side of the display area, and each of the chip on films comprising:
a film body;
gate driving chips and source driving chips, integrated and arranged on the film body, for providing gate driving signals and source driving signals; and
bonding wires, arranged on a side of the film body, for bonding and connecting grid wires of the gate driving chips to the scanning lines and for bonding and connecting source wires of the source driving chips to the data lines.

16. The display panel in claim 15, wherein the display panel at least comprises a first metal layer and a second metal layer, the scanning lines are arranged in the first metal layer, and the data lines are arranged in the second metal layer.

17. The display panel in claim 16, wherein the grid wires and the source wires are arranged in a same layer, the grid wires and the source wires are arranged in the first metal layer, or the grid wires and the source wires are arranged in the second metal layer.

18. The display panel in claim 16, wherein the grid wires and the source wires are arranged in different layers, the grid wires are arranged in one of the first metal layer and the second metal layer, and the source wires are arranged in another one of the first metal layer and the second metal layer.

19. The display panel in claim 18, wherein an insulating layer is disposed between the grid wires and the source wires.

20. The display panel in claim 15, wherein the display panel comprises a plurality of first fan-out lines and a plurality of second fan-out lines disposed at a side of the chip on films close to the display area, the first fan-out lines electrically connect the grid wires to the scanning lines through the bonding wires, and the second fan-out lines electrically connect the source wires to the data lines through the bonding wires.
